(19) United States
(12) Patent Application Publication
(10) Pub. No.: US 2010/0283773 A1
(43) Pub. Date: Nov. 11, 2010

(54) Driving integrated circuit and image display device including the same

(76) Inventor: Yong-Hun Kim, Seoul (KR)

Correspondence Address: LEE & MORSE, P.C., 3141 FAIRVIEW PARK DRIVE, SUITE 500, FALLS CHURCH, VA, 22042, US

(21) Appl. No.: 12/662,827

(22) Filed: May 5, 2010

(30) Foreign Application Priority Data
May 8, 2009 (KR) 10-2009-0040214
Jul. 31, 2009 (KR) 10-2009-0070484

(51) Int. Cl. G06F 3/038; G01R 35/00

(52) U.S. Cl. 345/211; 324/691

(57) ABSTRACT

A driving integrated circuit (IC) is provided. The driving IC includes a reference voltage setup circuit configured to output a reference voltage based on a test voltage and a load current control unit comparing a load voltage output from a load resistor with the reference voltage in response to a load current and maintaining the load current constant based on a result of the comparison.

### BACKGROUND

1. Field of the Invention

Embodiments relate to a driving integrated circuit (IC), and more particularly, to a driving IC capable of performing current calibration using an indirect sensing method and an image display device including the same.

2. Description of the Related Art

Driving ICs are employed to supply LEDs with a current for enabling the LEDs to emit light. Each LED may emit light having a brightness based on various characteristics of the LED, e.g., an amount of current flowing therethrough, a resistance of a sense resistor employed therewith, temperature, process, etc. Thus, driving ICs used with LEDs require a high-precision load current.

In order to secure the high-precision load current in the driving IC, a calibration circuit is required to compensate for variation of resistance of a sense resistor, for example, connected with an LED, with respect to temperature or processes. The calibration circuit also needs high calibration precision. A conventional calibration circuit has a sense resistor directly connected with an LED and corrects the load current of the LED through direct resistance sensing. For instance, the sense resistor in the calibration circuit is provided with a load current externally applied to the LED and outputs a sense voltage based on its resistance value and the load current.

However, since the conventional sense resistor has a resistance value of several ohms (Ω) in order to minimize the power loss of the calibration circuit, the sense voltage output from the sense resistor is low, which induces errors in the calibration circuit. As a result, the calibration circuit may not precisely correct the load current of the LED. Moreover, since the sense resistor is directly connected with the LED, the LED may be undesirably turned on while the calibration circuit performs current calibration using a direct resistance sensing method.

### SUMMARY

Embodiments are therefore directed to driving integrated circuits and image display devices, which substantially overrcome one or more of the problems due to the limitations and disadvantages of the related art.

It is therefore a feature of an embodiment to provide a driving integrated circuit (IC) including a current calibration circuit.

It is yet another feature of an embodiment to provide a driving IC that is adapted to supply a relatively more constant current based on a shorter calibration time to a respective LED, relative to comparable conventional devices.

It is therefore a separate feature of an embodiment to provide a driving IC that is adapted to supply a relatively more constant current to a respective LED, relative to comparable conventional devices.

It is therefore a separate feature of an embodiment to provide a driving IC that is adapted to supply a relatively more precisely controlled current to a respective LED, relative to comparable conventional devices.

It is therefore a separate feature of an embodiment to provide a driving IC that is adapted to more accurately determine a voltage across a sense resistor and to supply a relatively more constant current to a respective LED, relative to comparable conventional devices.

It is another feature of an embodiment to provide an image display device including a driving IC.

According to some embodiments of the present invention, the above and other features and advantages may be realized by providing a driving integrated circuit (IC), including a reference voltage setup circuit configured to output a reference voltage based on a test voltage and a load current control unit configured to compare a load voltage output from a load resistor with the reference voltage in response to a load current flowing in a load and maintain the load current constant based on a result of the comparison.

The driving IC may include a test resistor configured to output the test voltage in response to a test current. The load resistor may include at least two unit resistors connected in parallel and the test resistor may include at least two unit resistors connected in series. A resistance value of the test resistor may be an N multiple of a resistance value of the load resistor where N is a natural number.

The test resistor may be part of the load current control unit. The load and test resistors may be adjacent to one another on a semiconductor substrate.

The reference voltage setup circuit may include a calibration circuit configured to compare the test voltage with a calibration voltage and output at least one control signal according to a result of the comparison to control the load current control unit to maintain the load current constant. The at least one control signal may include a first current calibration control signal output to the load resistor to control a resistance value of the load resistor and a second current calibration control signal output to the reference voltage generator to control a magnitude of the reference voltage, wherein the calibration circuit outputs one of the first and second current calibration control signals.

The driving IC may include a switch controller configured to output a plurality of switching signals based on the at least one current calibration control signal and a switching unit including a plurality of switches respectively connected with the first unit resistors, the switching unit configured to perform switching operation in response to the switching signals to control the resistance value of the load resistor.

The test voltage may be an actual value output from a test resistor in response to a test current and the calibration voltage may be a theoretical value calculated from the test current and a resistance value of the test resistor.

The load current control unit may include a comparator configured to compare the load voltage with the reference voltage and output the comparison result and a controller connected with the load and configured to maintain a magnitude of the load current constant according to the comparison result output from the comparator.

The load may include a plurality of light emitting diodes (LEDs) and the driving IC is an LED driving IC.

The driving IC may include a test current source connected to the test resistor supplying the test current. The test current source may be turned off when calibration is complete.

The reference voltage setup circuit may include a calibration circuit configured to receive the test voltage. The reference voltage setup circuit may include a reference voltage generation circuit configured to output the reference voltage. The reference voltage generation circuit may be configured to output variable voltages to the calibration circuit and the calibration circuit includes a comparator comparing the variable voltages to the test voltage. The load current control unit may include a comparator configured to compare the load voltage with the reference voltage and output the comparison, the comparator in the load current control unit being a same type as the comparator in the calibration circuit.

According to some embodiments of the present invention, the above and other features and advantages may be realized by providing an image display device, including an image display unit configured to display an image signal, a light source configured to provide light to the image display unit, and a driving integrated circuit (IC) configured to maintain a load current applied from the outside to the light source constant. The driving IC may include a reference voltage setup circuit configured to output a reference voltage based on a test voltage, and a load current control unit configured to compare a load voltage output from a load resistor with the reference voltage in response to a load current flowing in a load and maintain the load current constant based on a result of the comparison.

The image display unit may be a large panel display unit. The load may be a plurality of light sources arranged in a periphery of the large panel display unit or a plurality of light sources arranged in a matrix adjacent the large panel display unit.

The image display unit may be a portable display unit. The load may be a plurality of light sources arranged in a periphery of the portable display unit or a plurality of light sources arranged in a matrix adjacent the portable display unit.

According to some embodiments of the present invention, the above and other features and advantages may be realized by providing a back light unit for an image display device, including a light source configured to provide light to the image display device and a driving integrated circuit (IC) configured to maintain a load current applied from an outside to the light source constant. The driving IC may include a reference voltage setup circuit configured to output a reference voltage based on a test voltage, and a load current control unit configured to compare a load voltage output from a load resistor with the reference voltage in response to a load current flowing in a load and maintain the load current constant based on a result of the comparison.

The light source may include a plurality of light emitting diode (LED) sources arranged in a periphery of the back light unit or a plurality of light emitting diode (LED) sources arranged in a matrix.

According to some embodiments of the present invention, the above and other features and advantages may be realized by providing a multi-channel driving system, including a plurality of driving integrated circuits (ICs), a reference voltage setup circuit adapted to supply respective reference voltages to each of the plurality of driving ICs, the reference voltage generation circuit including a reference voltage source adapted to supply source reference voltages based on test voltages, and a calibration circuit configured to receive a sensed voltage from each of the driving ICs and to generate a respective reference voltages in accordance with each of the sensed voltages and a respectively selected one of the source reference voltages.

At least one of the reference voltage source and the calibration circuit may be common to the plurality of driving ICs.

According to some embodiments of the present invention, the above and other features and advantages may be realized by providing a method of driving a light source, including calibrating a reference voltage in accordance with a test voltage, supplying the reference voltage to a current driver when calibrating is complete, and driving the light source with the current driver.

The method may include, when calibrating is complete, stopping calibrating.

The method may include generating the test voltage using a test resistor, adjacent a resistor in the current driver, connected to a test current source. The test current source may be turned off when calibrating is complete.

### BRIEF DESCRIPTION OF THE DRAWINGS

The above and other features and advantages will become more apparent by describing in detail exemplary embodiments thereof with reference to the attached drawings in which:

FIG. 1 illustrates a schematic block diagram of a driving integrated circuit (IC) according to some embodiments of the present invention;

FIG. 2 illustrates a schematic block diagram of a driving IC according to other embodiments of the present invention;

FIG. 3 illustrates a layout of a plurality of unit resistors illustrated in FIG. 2;

FIG. 4 illustrates a schematic block diagram of a driving IC according to yet other embodiments of the present invention;

FIG. 5 illustrates a more detailed schematic block diagram of a driving IC of FIG. 4;

FIG. 6 illustrates a schematic diagram of the driving IC of FIG. 5 including a more detailed schematic diagram of an exemplary embodiment of the calibration circuit employable therein and an exemplary timing diagram of a variable reference voltage employable therein;

FIG. 7 illustrates a schematic diagram of the driving IC of FIG. 4 including a more detailed schematic diagram of an exemplary embodiment of the calibration circuit employable therein;

FIG. 8 illustrates a schematic diagram of the driving IC of FIG. 4 including a more detailed schematic diagram of an exemplary embodiment of the reference voltage generation circuit employable therein;

FIG. 9 illustrates a timing diagram of exemplary signals employable by exemplary embodiments of the reference voltage generation circuit and the calibration circuit of FIG. 8;

FIG. 10 illustrates a schematic diagram of still another exemplary embodiment of an driving IC;

FIG. 11 illustrates a schematic diagram of an exemplary multi-channel embodiment of the driving IC;

FIG. 12 illustrates a flowchart of the current calibrating operations of the driving IC illustrated in FIG. 1;

FIG. 13 illustrates waveforms according to the flowchart illustrated in FIG. 12;

FIG. 14 illustrates a schematic block diagram of an image display device including the driving IC in accordance with any of the embodiments;

FIG. 15 illustrates a block diagram of an exemplary back light unit for use with an edge type display employing driving IC in accordance with any of the embodiments;

FIG. 16 illustrates a block diagram of an exemplary back light unit for use with a direct type display employing driving IC in accordance with any of the embodiments; and

FIG. 17 illustrates a block diagram of an exemplary back light unit for use with a mobile display employing driving IC in accordance with any of the embodiments.

### DETAILED DESCRIPTION OF THE EMBODIMENTS

This application claims priority under 35 U.S.C. §119 to Korean Patent Application No. 10-2009-0040214, filed on 8 May 2009, and to Korean Patent Application No. 10-2009-0070484, filed on 31 Jul. 2009, in the Korean Intellectual Property Office, the disclosures of both of which are incorporated herein by reference.

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

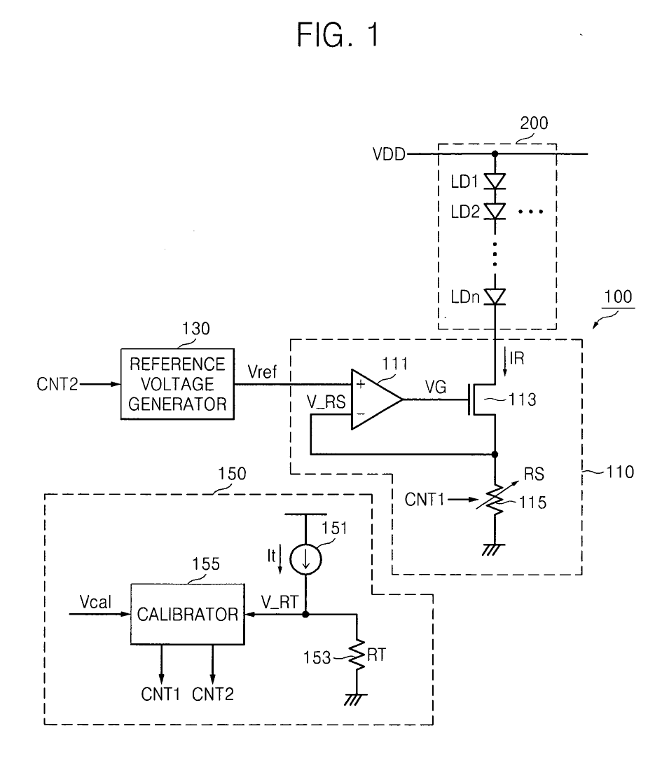

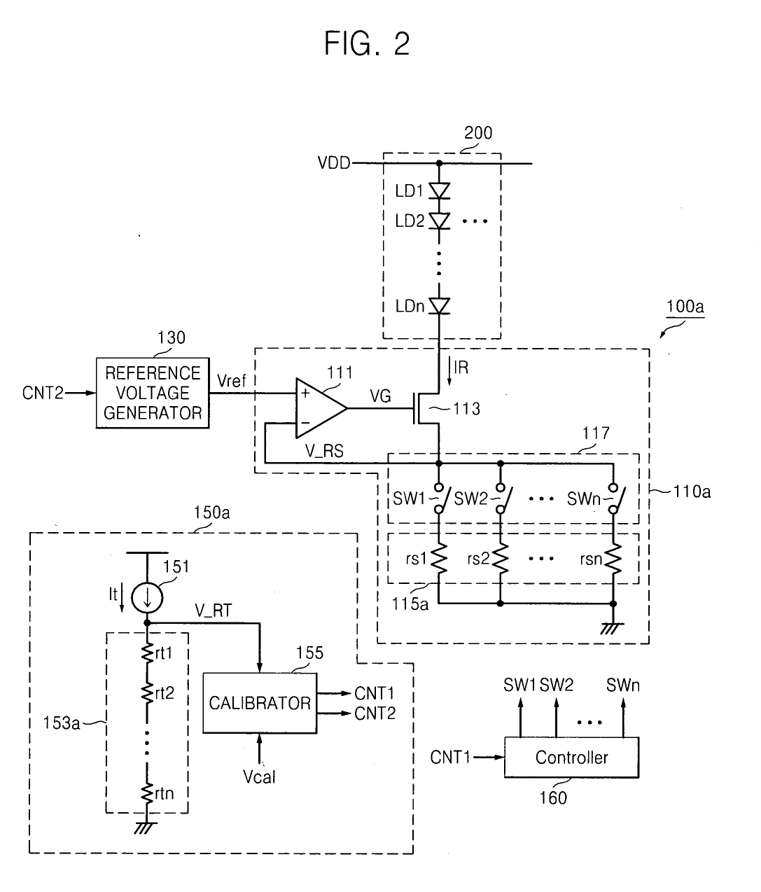

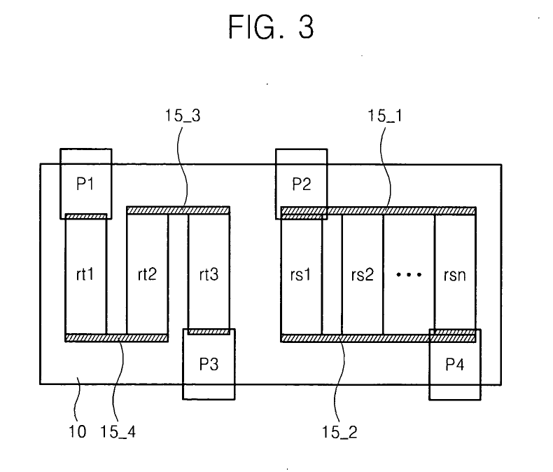

FIG. 1 illustrates a schematic block diagram of a driving integrated circuit (IC) 100 according to some embodiments of the present invention. FIG. 2 is a schematic block diagram of a driving IC 100a according to other embodiments of the present invention. FIG. 3 is a layout of a plurality of unit resistors illustrated in FIG. 2. Referring to FIG. 1, the driving IC 100 may include a load current control unit 110, and a reference voltage setup circuit including a reference voltage generator 130 and a current calibration circuit 150. The load current control unit 110 may be connected with a load 200 and maintain a load current IR flowing in the load 200 constant.

The load 200 may include a plurality of light emitting diode (LED) strings each of which may include a plurality of LEDs LD1, LD2, . . . , LDn connected in series. The load 200 may be used as a light source in an image display device, e.g., a liquid crystal display (LCD) or an organic light emitting diode (OLED) display. The load 200 may receive a predetermined driving voltage VDD from an external device, e.g., a DC-DC converter (not shown), to operate.

The load current control unit 110 may include a comparator 111, a controller 113, and a first resistor 115. The comparator 111 may compare a reference voltage Vref output from the reference voltage generator 130 with a load voltage V_RS output from the first resistor 115 and output a control voltage VG for controlling the operation of the controller 113 according to a result of the comparison. At this time, the load voltage V_RS output from the first resistor 115 may be the product of the load current IR provided from the load 200 through the controller 113 and a resistance RS of the first resistor 115.

The controller 113 may function as a current source which maintains the load current IR flowing in the load 200 constant based on the control voltage VG output from the comparator 111. The controller 113 may be implemented by a switching element such as a transistor. The control voltage VG output from the comparator 111 may control a gate voltage of a gate of the controller 113.

The first resistor 115 may sense the load current IR provided from the load 200 through the controller 113 and output the load voltage V_RS corresponding to the product of the load current IR and the resistance RS of the first resistor 115 based on the sensing result. The first resistor 115 may be a variable resistor having a variable resistance and may control the resistance RS based on a control signal, e.g., a first current calibration control signal CNT1, output from a calibrator 155, which will be described later.

In other words, the load current control unit 110 may sense the load current IR flowing in the load 200 using the first resistor 115 and may control the controller 113 based on a result of comparing the load voltage V_RS output according to the sensing result with the reference voltage Vref, thereby maintaining the load current IR flowing in the load 200 constant. At this time, the resistance value of the first resistor 115 may change due to an environment in which the driving IC 100 is used, for example, temperature or humidity, or due to an error in a process of manufacturing the first resistor 115. The change in the resistance value of the first resistor 115 results in the change in magnitude of the load voltage V_RS. As a result, the load current control unit 110 may not maintain the load current IR flowing in the load 200 constant. To prevent this situation, the first resistor 115 compensates for the change in the resistance value based on the first current calibration control signal CNT1 output from the calibrator 155 through the current calibration of the current calibration circuit 150. The compensation of the resistance value enables the load current control unit 110 to maintain the load current IR flowing in the load 200 constant.

Alternatively, the first resistor 115 may include a plurality of resistors connected in parallel. Referring to FIG. 2, for example, a first resistor 115a includes a plurality of first unit resistors rs1, rs2, . . . , rsn connected in parallel. The first unit resistors rs1 through rsn may be connected with a plurality of switches, respectively, included in a switching unit 117. The entire resistance value of the first resistor 115a may be changed by the switching operation of the switching unit 117.

The switching unit 117 may control the operation of the switches according to the first current calibration control signal CNT1 output from the calibrator 155 included in a current calibration circuit 150a. In other words, the driving IC 100a illustrated in FIG. 2 may further include a switch controller 160, which may output a plurality of switching signals SW1, SW2, . . . , SWn based on the first current calibration control signal CNT1 output from the calibrator 155. The switching unit 117 may control the operation of the switches based on the switching signals SW1 through SWn provided by the switch controller 160, thereby changing the entire resistance value of the first resistor 115a.

Although the switches in the switching unit 117 are respectively connected in series with the first unit resistors rs1 through rsn in FIG. 2, the present invention is not restricted to the embodiments illustrated in FIG. 2. In other embodiments of the present invention, the switches in the switching unit 117 may be respectively connected in parallel with the first unit resistors rs1 through rsn. In a case where the switches in the switching unit 117 are respectively connected in series with the first unit resistors rs1 through rsn, the entire resistance value of the first resistor 115a can be controlled when each of the switches in the switching unit 117 is opened by one of the switching signals S1 through Sn output from the switch controller 160. In another case where the switches in the switching unit 117 are respectively connected in parallel with the first unit resistors rs1 through rsn, the entire resistance value of the first resistor 115a can be controlled when each of the switches in the switching unit 117 is closed by one of the switching signals SW1 through SWn output from the switch controller 160.

Referring back to FIG. 1, the reference voltage generator 130 may output the reference voltage Vref to the load current control unit 110. The reference voltage generator 130 may control the magnitude of the reference voltage Vref based on a control signal, e.g., a second current calibration control signal CNT2, output from the current calibration circuit 150a.

The current calibration circuit 150a may compare a test voltage V_RT generated based on a test current “It” with a calibration voltage Vcal and output at least one calibration signal, e.g., the first current calibration control signal CNT1 and/or the second current calibration control signal CNT2, according to a result of the comparison. The current calibration circuit 150a may include a test current generator 151, a second resistor 153a, and the calibrator 155.

When the driving IC 100a performs current calibration, the test current generator 151 may generate and output the test current “It” having a predetermined magnitude. The test current generator 151 may be implemented by a single constant current source and may output the test current “It” having a magnitude of about 100 μA.

The second resistor 153a may be connected with the test current generator 151 and output the test voltage V_RT based on the test current “It”. The resistance value of the second resistor 153a may be the same as or an N multiple of the resistance value of the first resistor 115a, where N is a natural number. The second resistor 153a may be connected in series with the test current generator 151.

The calibrator 155 may compare the test voltage V_RT output from the second resistor 153a with the calibration voltage Vcal. The calibration voltage Vcal may be a theoretical voltage corresponding to the product of the test current “It” and the resistance value of the second resistor 153a. The test voltage V_RT may be an actual voltage output from the second resistor 153a during the operation of the current calibration circuit 153a. The calibrator 155 may output at least one control signal, e.g., the first current calibration control signal CNT1 and/or the second current calibration control signal CNT2, according to the result of comparing the calibration voltage Vcal with the test voltage V_RT. The first current calibration control signal CNT1 may be a signal for controlling the resistance value of the first resistor 115 and the second current calibration control signal CNT2 may be a signal for controlling the reference voltage Vref of the reference generator 130.

Alternatively, the second resistor 153 may include a plurality of resistors connected in series. Referring to FIG. 2, for instance, a second resistor 153a may include a plurality of second unit resistors rt1, rt2, . . . , rtn connected in series. At this time, a resistance value of each of the second unit resistors rt1 through rtn may be the same as that of one of the first unit resistors rs1 through rsn. Accordingly, the test voltage V_RT output from the second resistor 153a may be the product of the entire resistance value of the second resistor 153a, i.e., the sum of resistance values of the respective second unit resistors rt1 through rtn, and the test current “It”. The first unit resistors rs1 through rsn of the first resistor 115a may be disposed adjacent to the second unit resistors rt1 through rtn of the second resistor 153a.

Referring to FIGS. 2 and 3, the first unit resistors rs1 through rsn and the second unit resistors rt1 through rtn may be formed adjacent to each other on a single semiconductor substrate 10. For instance, the first unit resistors rs1 through rsn may be formed in a first area of the semiconductor substrate 10, while the second unit resistors rt1 through rtn may be formed in a second area thereof. In the embodiments illustrated in FIG. 3, three second unit resistors rt1, rt2 and rt3 are formed on the semiconductor substrate 10 to constitute the second resistor 153a.

The first unit resistors rs1 through rsn may be connected in parallel with one another via connecting elements, e.g., a first connecting element 15_1 and a second connecting element 15_2, and may be connected between outsides, i.e., the switching unit 117 and a ground GND via pads P2 and P4. The second unit resistors rt1 through rtn may be connected in series with one another via connecting elements, e.g., a third connecting element 15_3 and a fourth connecting element 15_4, and may be connected between the outsides, i.e., the test current generator 151 and the calibrator 155 via pads P1 and P3.

Meanwhile, a resistance value of each of the first unit resistors rs1 through rsn in the first resistor 115a may be the same as that of one of the second unit resistors rt1 through rtn in the second resistor 153a. Accordingly, an error in the resistance value occurring in each of the second unit resistors rt1 through rtn may be considered the same as that occurring in one of the first unit resistors rs1 through rsn. Therefore, when the calibrator 155 of the current calibration circuit 150′ outputs a control signal based on a result of comparing the test voltage V_RT with the calibration voltage Vcal, it may be determined that an error has occurred in a resistance value of each of the second unit resistors rt1 through rtn and the same error has occurred in a resistance value of each of the first unit resistors rs1 through rsn. Consequently, the calibrator 155 can perform current calibration by adjusting the resistance value of the first resistor 115a or the magnitude of the reference voltage Vref using the first current calibration control signal CNT1 or the second current calibration control signal CNT2.

In other words, the current calibration circuit 150 or 150a illustrated in FIG. 1 or 2 calibrates current in the driving IC 100 or 100a using the test current generator 151 and the second resistor 153 or 153a, which are formed in a separated area, thereby preventing the turn-on of a load, e.g., the turn-on of the LEDs LD1 through LDn, which occurs when a conventional driving IC (not shown) performs current calibration using a load current. In addition, since the second unit resistors rt1 through rtn of the second resistor 153a illustrated in FIG. 2 are connected in series, the second resistor 153a may have a bigger resistance value than the first resistor 115a in which the first unit resistors rs1 through rsn are connected in parallel. Accordingly, even when the test current generator 151 of the current calibration circuit 150a generates and outputs test current “It” which is small, the second resistor 153a can output the test voltage V_RT which is large due to a large resistance value. As a result, the current calibration circuit 150a can reduce power consumed while the driving IC 100a performs current calibration.

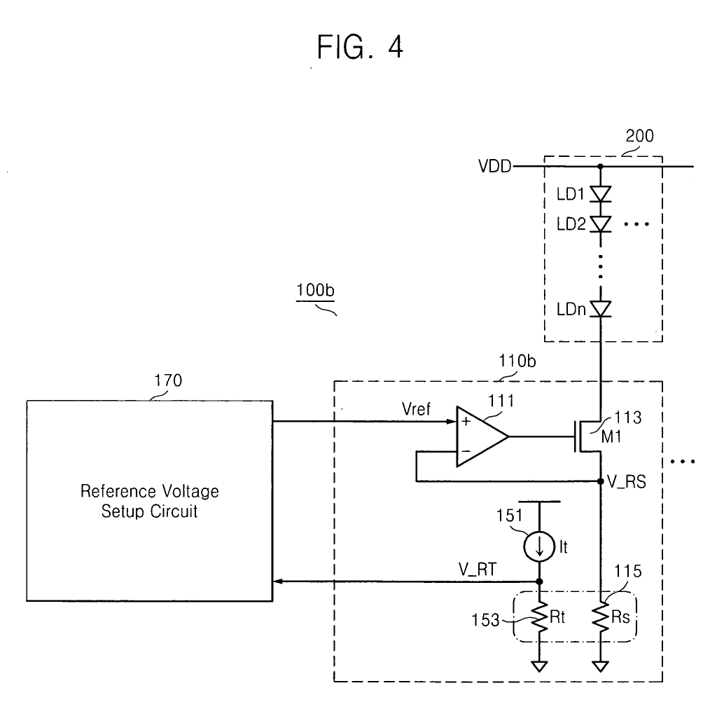

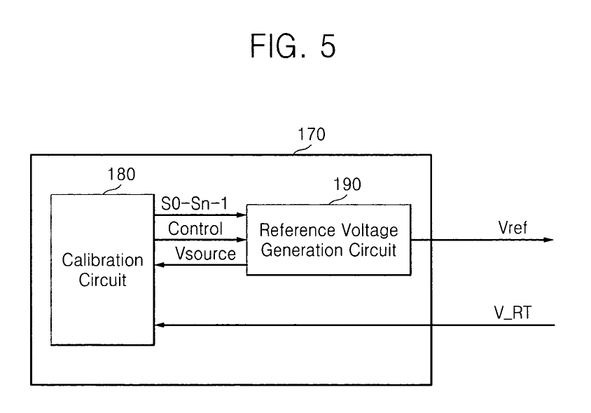

FIG. 4 illustrates a schematic diagram of yet another exemplary embodiment of a driving IC 100b. The driving IC 100b may include a load current control unit 110b and a reference voltage setup circuit 170. As illustrated in FIG. 5, the reference voltage setup circuit 170 may include a reference voltage generator 190 and a calibration circuit 180. The load current control unit 110b may be connected to the load 200.

In contrast with previous embodiments, the first resistor 115 and the second resistor 153 may be arranged on a substantially same portion of a semiconductor substrate (not shown), e.g., may be arranged adjacent to each other on a single semiconductor substrate. That is, e.g., the second resistor 153 may be a replica of the first resistor 115 and may be arranged adjacent to the first resistor 153 on the semiconductor substrate. In embodiments, the first resistor 115 and the second resistor 153 may have exactly a same resistance and exactly same characteristics, e.g., change in resistance due to temperature change, etc., by, e.g., fabricating the first resistor 115 and the second resistor 153 under same processing conditions and specifications. Alternatively, the first resistor may be implemented as the first resistor 115a and the second resistor may be implemented as the second resistor 153a of FIG. 2. As illustrated in FIG. 2, while the resistors forming the first resistor 115a and the second resistor 153a may have the same resistance and be formed under the same conditions, these resistors may be connected in parallel for the first resistor 115a and in series for the second resistor 153a. The load current control unit 110b may then also include the switching unit 117 of FIG. 2.

Referring again to FIG. 4, the first resistor 115 and the second resistor 153 may be arranged adjacent to each other on a same region of a semiconductor substrate, may include exactly same materials, may be fabricated under exact same processing conditions, e.g., simultaneously fabricated together, may have a same exact pattern and/or size, etc., other than the connections there between when more than one resistor is employed. Thus, even when an environment of first resistor 115 and second resistor 153 changes, e.g., humidity and/or temperature change, etc., the first resistor 115 and the second resistor 153 may still have same and/or substantially resistance values. Therefore, when a same current is supplied to each of the first resistor 115 and the second resistor 153, the load voltage V_RS across the first resistor 115 and the test voltage V_RT across the second resistor 153, or the relationship therebetween, may be completely and/or substantially same irrespective of, e.g., an environment around the first and the second resistors 115, 153.

By providing the first resistor 115 and the second resistor 153 adjacent one another, the test voltage V_RT output from the second resistor 153 may in effect be supplying the load voltage V_RS output from the first resistor 115 to the reference voltage setup circuit 170. The reference voltage setup circuit 170 may then generate a reference voltage Vref based on the generated voltage signal V_RT supplied from the load current control unit 110b.

FIG. 5 illustrates a schematic diagram of the driving IC 100b of FIG. 4 including a more detailed schematic diagram of an exemplary embodiment of the reference voltage setup circuit 170 employable therein. In general, features of elements described above will not be repeated again for FIG. 5.

Referring to FIG. 5, in some embodiments, the reference voltage setup circuit 170 may include a calibration circuit 180 and/or a reference voltage generation circuit 190. The test voltage V_RT generated, based on the second resistor 153 and the current source 151, may be supplied to the calibration circuit 180. The calibration circuit 180 may employ the test voltage V_RT to carry out a calibration function while the driving IC 100b is operating, e.g., during an initial period of operation of the driving IC 100b.

In embodiments including the reference voltage generation circuit 190, the reference voltage generation circuit 190 may supply the calibration circuit 180 with a variable reference voltage Vsource. The variable reference voltage Vsource may be employed by the calibration circuit 180 to determine a voltage level of the test voltage V_RT. The reference voltage signals S0 through Sn-1 and the control signal Control may correspond to a calibration function based on the test voltage V_RT and/or the variable reference voltage Vsource. The calibration circuit 180 may supply reference voltage signals S0 through Sn-1 and the control signal Control to the reference voltage generation circuit 190.

In such embodiments, the reference voltage generation circuit 190 may employ the reference voltage signals S0 through Sn-1 and the control signal Control to generate and output the reference voltage Vref to the comparator 111 of the load control circuit unit 110b.

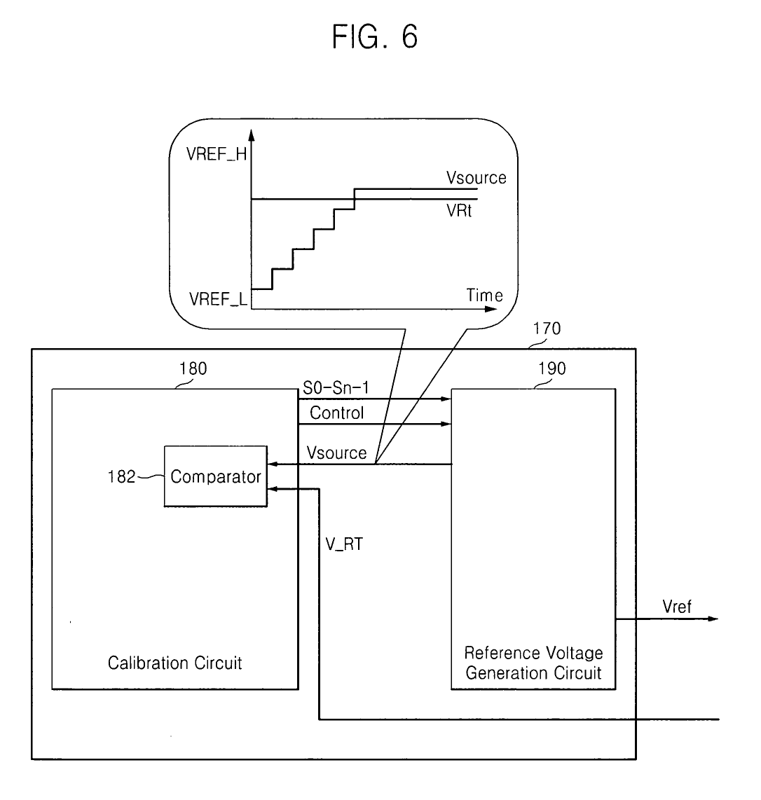

FIG. 6 illustrates a schematic diagram of the driving IC 100b of FIG. 5 including a more detailed schematic diagram of the calibration circuit 170 and an exemplary timing diagram of the variable reference voltage Vsource employable therein. In general, features of elements described above will not be repeated again for FIG. 6.

Referring to FIG. 6, the calibration circuit 180 may include a comparator 182. The test voltage V_RT and the variable reference voltage Vsource may be respectively input to input terminals of the comparator 182. As discussed above, in some embodiments, the calibration circuit 180 may employ the variable reference voltage Vsource to determine a voltage level of the test voltage V_RT. In some embodiments, the comparator 111 of load control circuit unit 110b and the comparator 182 of the calibration circuit 180 may be the same, e.g., have same specifications and characteristics, and may achieve a noise canceling affect and reduce and/or minimize calibration error.

The comparator 182 may output a high signal or a low signal based on a comparison result of the test voltage V_RT and the variable reference voltage Vsource. If the test voltage V_RT and the variable reference voltage Vsource have a same level, the comparator 182 may output a high level signal. If the test voltage V_RT and the variable reference voltage source Vsource do not have a same level, the comparator 182 may output a low level signal and a level of the variable reference voltage Vsource may be sequentially increased, as shown, e.g., in FIG. 6, and the comparator 182 may perform another comparison. Such a process of comparing and increasing the variable reference voltage Vsource may be repeated until the test voltage V_RT and the variable reference voltage Vsource have a same level, and the level of the test voltage V_RT may be determined.

As discussed above, the calibration circuit 182 may generate and supply reference voltage signals S0 through Sn-1 and the control signal Control to the reference voltage generation circuit 190 based on the determined level of the test voltage V_RT. In such embodiments, the reference voltage generation circuit 190 may employ the reference voltage signals S0 through Sn-1 and the control signal Control to generate and output the reference voltage Vref to the comparator 111 of the load control circuit unit 110b.

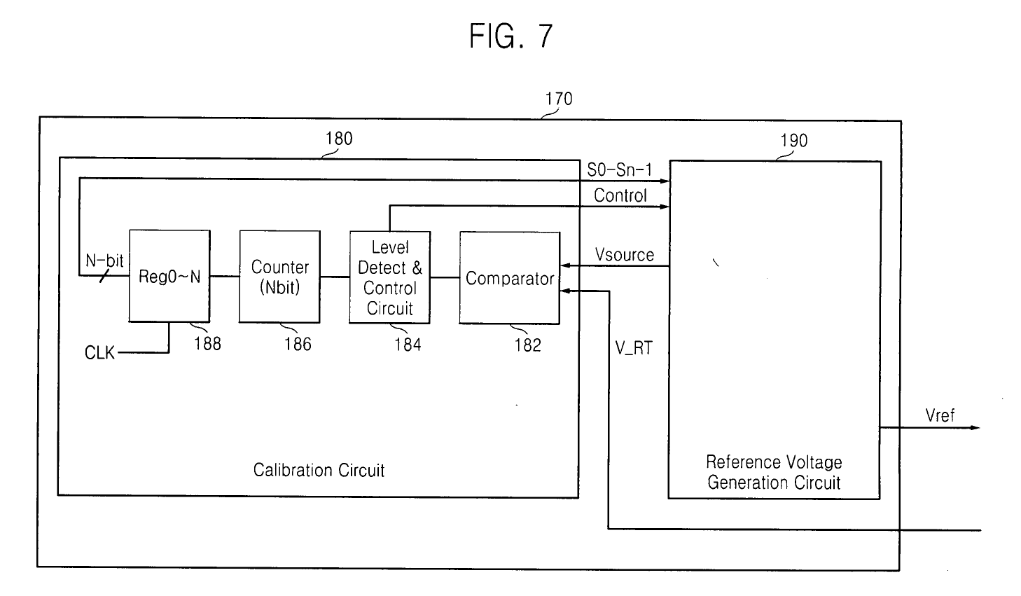

FIG. 7 illustrates a schematic diagram of the driving IC 100b of FIG. 4 including a more detailed schematic diagram of an exemplary embodiment of the calibration circuit 180 employable therein. In general, features of elements described above will not be repeated again for FIG. 7.

Referring to FIG. 7, in addition to the comparator 182, the calibration circuit 180 may further include a level detection and control circuit 184, a counter 186, and a register 188. The counter 186 may be an N-bit counter and the register 188 may be an N-bit register. As discussed above, the comparator 182 may output a high level signal or a low level signal based on a comparison between the variable reference voltage Vsource and the test voltage V_RT. Referring to FIG. 7, the level detection and control circuit 184 may receive the output signal from the comparator 182 and, based on the level of the output signal of the comparator 182, the level detection and control circuit 184 may control an operation of the counter 186. The level detection and control circuit 184 may also supply the control signal Control, based on the level of the output signal of the comparator 182, to the reference voltage generation circuit 190.

The counter 186 may count a number of comparisons performed by the comparator 182. The number of comparisons counted by the counter 186 may be stored in the register 188. The reference voltage generation circuit 190 may be supplied with the number stored in the register 188 as the reference voltage signals S0 through Sn-1. The reference voltage signals S0 through Sn-1 may be employed by the reference voltage generation circuit 190 to set the reference voltage Vref to be supplied to the load current control unit 110b.

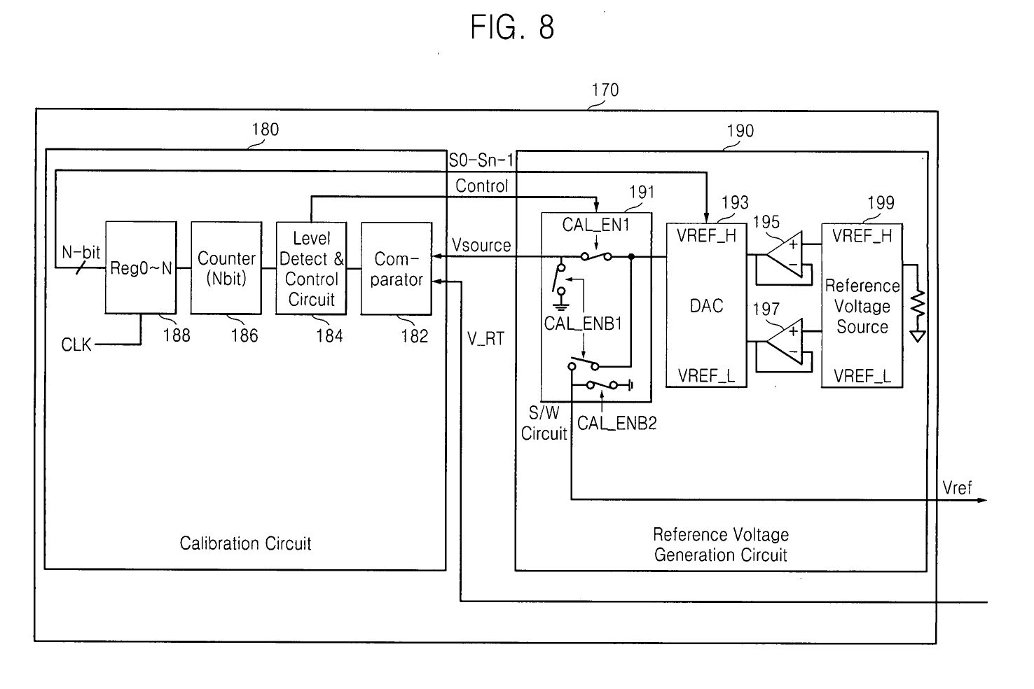

FIG. 8 illustrates a schematic diagram of the reference voltage setup circuit 170 of FIG. 4 including a more detailed schematic diagram of an exemplary embodiment of the reference voltage generation circuit 190 employable therein. In general, features of elements described above will not be repeated again for FIG. 8.

Referring to FIG. 8, the reference voltage generation circuit 190 may include a switching circuit 191, a digital-analog-converter (DAC) 193, operational amplifiers 195, 197, and a reference voltage source 199. The reference voltage source 199 may generate and supply the DAC 193 with a plurality of reference voltages via, e.g., the operational amplifiers 195, 197.

The reference voltage source 199 may be adapted to generate and supply a low reference voltage VREF_L and a high reference voltage VREF_H based on a reference voltage VREF. For example, levels of the high reference voltage VREF_H and the low reference voltage VREF_L may be set to include the range of voltage distributions to be corrected. For example, assuming that a voltage when error is 0% is VREF, when the range of a voltage distributions to be corrected is ±50%, the high reference voltage VREF_H may be set as follows: VREF_H=VREF+50% (VREF), and the low reference voltage VREF_L as follows: VREF_L=VREF−50% (VREF).

The DAC 193 may select, e.g., one reference voltage among the variable reference voltages supplied from the reference voltage source 199 based on the reference voltage signals S0 through Sn-1 supplied from the register 188 of the calibration circuit 180. Calibration may be performed until the test voltage V_RT has a same voltage as the variable reference voltage Vsource. In some embodiments, when calibration is completed, e.g., when V_RT=Vsource, the selected variable reference voltage Vsource may no longer be supplied to the calibration circuit 180. In such embodiments, e.g., a path between the reference voltage generation circuit 190 and the calibration circuit 180 for supplying the variable reference voltage Vsource may be disconnected when calibration is completed.

When calibration is completed, the selected reference voltage signal from the reference voltage source 199 may be supplied to the switching circuit 191. The switching circuit 191 may supply the selected reference voltage signal selected by the DAC 193 to the load current control unit 110b. More particularly, the reference voltage generation circuit 190 may supply the selected reference voltage signal to the comparator 111 of the load current control unit 110b via the switching circuit 191 based on the control signal Control supplied from the level detection and control circuit 184 of the calibration circuit 180.

The switching circuit 191 may include a plurality of switches for selectively controlling pathways between the switching circuit 191 and the calibration circuit 180 and/or the load current control unit 110b. More particularly, the switches of the switching circuit 191 may selectively control pathways between the switching circuit 191 and the comparator 182 of the calibration circuit 180 and between the switching circuit 191 and the comparator 111 of the load current control unit 110b.

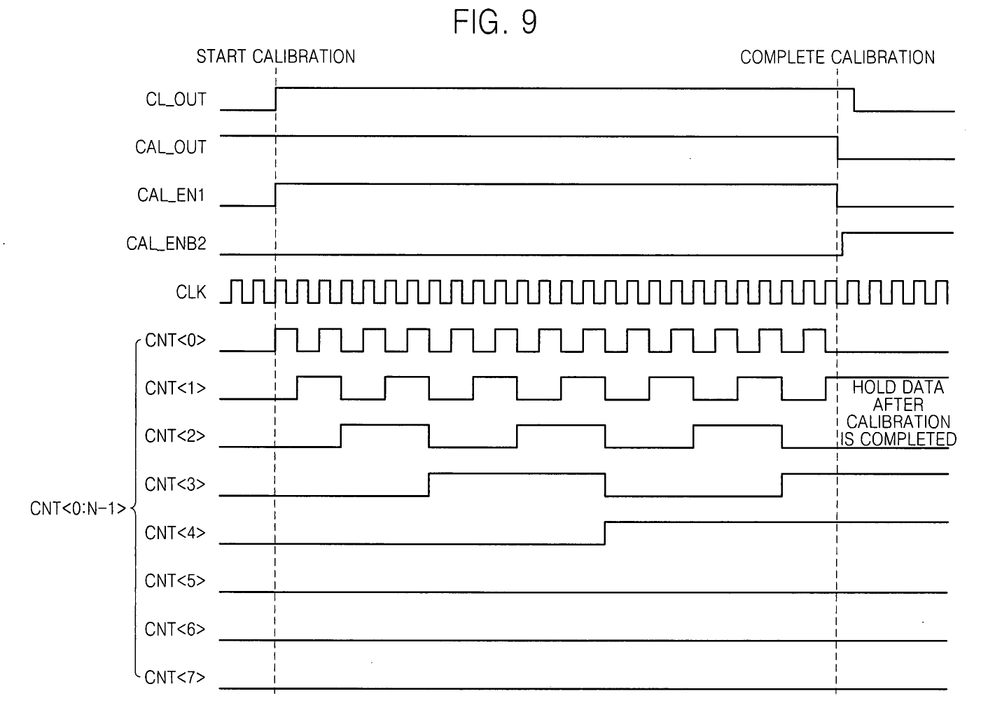

FIG. 9 illustrates a timing diagram of exemplary signals employable by the reference voltage generation circuit 190 and the calibration circuit 180. Referring to FIG. 9, at the start of a calibration cycle, a calibration control signal CAL_OUT may be high, a first calibration enable signal CAL_EN1 may be high, a first calibration enable bar signal CAL_ENB1 may be low, and a second calibration enable bar signal CAL_ENB2 may be low. The calibration control signal CAL_OUT may correspond to the control signal Control supplied from the level detection and control circuit 184 to the reference voltage generation circuit 190. With the second calibration enable bar signal CAL_ENB2 low during the calibration cycle, a corresponding switch of the switching circuit 191 may be closed and a path may exist between the DAC 193 and ground during that time. Further, with the first calibration enable signal CAL_EN1 high during the calibration cycle, a corresponding switch of the switching circuit 191 may be closed and a path between the DAC 193 and calibration circuit 180 for supplying variable reference voltage Vsource to the comparator 182 may exist during that time. With the first calibration enable bar signal CAL_ENB1 low, corresponding switches of the switching circuit 191 are open.

More particularly, during calibration, as discussed above, the comparator 182 may output a high level signal or a low level signal based on a comparison between the variable reference voltage Vsource and the test voltage V_RT. Referring to FIG. 8, the level detection and control circuit 184 may receive the output signal from the comparator 182 and, based on the level of the output signal of the comparator 182, the level detection and control circuit 184 may control an operation of the counter 186. The level detection and control circuit 184 may also supply a control signal Control, which may correspond to the calibration control signal CAL_OUT of FIG. 9, based on the level of the output signal of the comparator 182, to the reference voltage generation circuit 190.

As discussed above, the counter 186 may count a number of comparisons performed by the comparator 182. The number of comparisons counted by the counter 186 may be stored in the register 188. The reference voltage generation circuit 190 may be supplied with the number stored in the register 188 as the reference voltage signals S0 through Sn-1. More particularly, referring to FIG. 9, counting signals CNT 0 to CNT 7, respectively corresponding to reference voltage signals S0 through Sn-1, may be supplied from the register 188 of the calibration circuit 180 to the reference voltage generation circuit 190 based on a clock signal CLK. The reference voltage signals S0 through Sn-1 may be employed by the reference voltage generation circuit 190 to set the reference voltage Vref to be supplied to the load current control unit 110b.

At the end of a calibration cycle, the calibration control signal CAL_OUT may be low, the first calibration enable signal CAL_EN1 may be low, the first calibration enable bar signal CAL_ENB1 may be high, and the second calibration enable bar signal CAL_ENB2 may be high. Referring to FIG. 9, in such embodiments, with the second calibration enable bar signal CAL_ENB2 high after the calibration cycle, the corresponding switch of the switching circuit 191 may be open. Further, with the first calibration enable signal CAL_EN1 low after the calibration cycle, the corresponding switch of the switching circuit 191 may be open and a path between the DAC 193 and calibration circuit 180 for supplying variable reference voltage Vsource to the comparator 182 may not exist during that time. With the first calibration enable bar signal CAL_ENB1 high, the corresponding switches of the switching circuit 191 may be closed and a path may exist between the DAC 193 and the comparator 111 of the load control current unit 110b during that time. Thus, the selected reference voltage signal Vref may be supplied to the comparator 111 of the load current control unit 110b after calibration is completed.

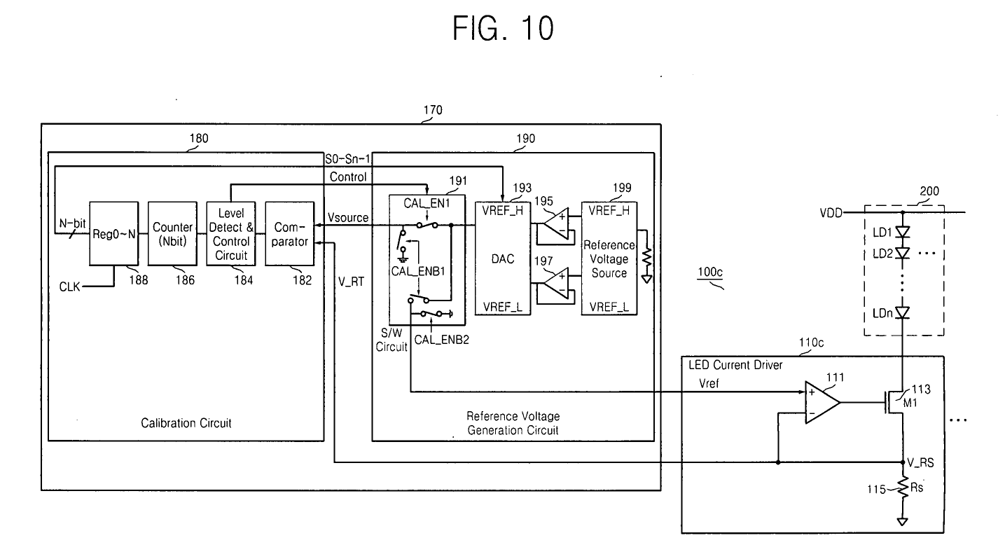

FIG. 10 illustrates a schematic diagram of another exemplary embodiment of a driving IC 100c including exemplary embodiments of the reference voltage generation setup circuit 170 employable therein. The exemplary embodiment of the driving IC 100c illustrated in FIG. 10 substantially corresponds to the exemplary embodiment of the driving IC illustrated in FIG. 4. Therefore, in general, only differences between the exemplary driving IC 100b of FIG. 4 and the exemplary driving IC 100c of FIG. 10 will be described below.

The exemplary driving IC 100b of FIG. 4 illustrates an exemplary embodiment of an indirect sensing method in which the load voltage V_RS is indirectly sensed, while the exemplary driving IC 100c of FIG. 10 illustrates an exemplary embodiment of a direct sensing method in which the load voltage V_RS is directly sensed. More particularly, referring to FIG. 10, in the exemplary driving IC 100c, the load voltage V_RS is directly supplied to the comparator 111 of a load current control unit 110c and the comparator 182 of the calibration circuit 180, e.g., there is no resistor corresponding to the second resistor 153 of FIG. 4. The calibration circuit 180 and the reference voltage generation circuit 190 may operate as discussed above with regard to FIG. 10, but employing the directly sensed load voltage V_RS instead of the indirectly sensed load voltage V_RS, via the directly sensed test voltage V_RT. Of course, the first resistor may be implemented using the first resistor 115a of FIG. 2, along with the switching unit 117.

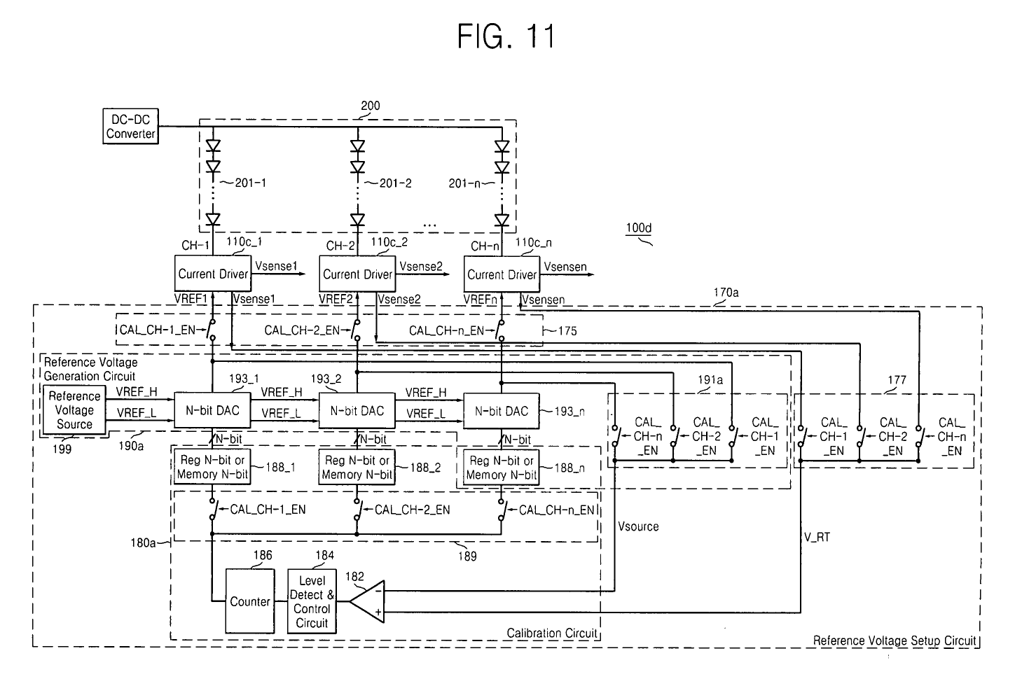

FIG. 11 illustrates a schematic diagram of an exemplary multi-channel embodiment of a driving IC system 100d. Like reference numerals refer to like elements throughout the application, and thus, in general, only differences between the exemplary embodiment of FIG. 4 and the exemplary embodiment of FIG. 11 will be described below. Referring to FIG. 11, the multi-channel driving IC 100d may include a reference voltage setup circuit 170a. A plurality of current drivers 210_1 to 210_{—}n may be provided between the load 200 and the reference voltage setup circuit 170a.

The plurality of LEDs may be arranged into groups of strings 201_1, 201_2, . . . 201_{—}n, each string including two or more of the LEDs coupled in series. Each of the plurality of current drivers 110c_1 to 110c_{—}n may each be coupled to a respective one of the strings of LEDs 201-1˜201-n

The reference voltage setup circuit 170a may include a calibration circuit 180a and a reference voltage generation circuit 190a. The calibration circuit 180a may be commonly employed by one, some, or all of the strings of the LEDs 201-1˜201-n. The reference voltage setup circuit 170a may also include a channel switching circuit 175 including a plurality of switches to provide a connection between the reference voltage generation circuit 190a and the plurality of current drivers 110c_1 to 110c_{—}n in order to supply corresponding reference voltages Vref1, Vref2, . . . , Vrefn to the plurality of current drivers 110c_1 to 110c_{—}n. The reference voltage setup circuit 170a may also include a channel switching circuit 177 including a plurality of switches to provide a connection between the calibration circuit 180a and the plurality of current drivers 110c_1 to 110c_{—}n in order to supply corresponding sensed voltages Vsense1, Vsense2, . . . , Vsensen from the plurality of current drivers 110c_1 to 110c_{—}n thereto as the test voltage V_RT. The switches in the channel switching circuits 175, 177 may be controlled in accordance with calibration enable signals for each channel CAL_CH-1_EN, CAL_CH-2_EN, . . . CAL_CH-n_EN.

The reference voltage generation circuit 190a may include the reference voltage source 199, a plurality of N-bit DACs 193_1 to 193_{—}n, and a switching circuit 191a including a plurality of channel switches controlled in accordance with calibration enable signals for each channel CAL_CH-1_EN, CAL_CH-2_EN, . . . CAL_CH-n_EN in order to provide corresponding Vref1 to Vrefn to the current driver 110c_1 to 110c_{—}n. The reference voltage source 199 may be commonly employed by one, some, or all of the strings 201_1, 201_2, . . . , 201_{—}n.

The calibration circuit 180a may include the comparator 182, the level detect and control circuit 184, the counter 186, a plurality of N-bit registers/memories 188_1 to 188_{—}n, and a switching unit 189 having a plurality of switches controlled in accordance with calibration enable signals for each channel CAL_CH-1_EN, CAL_CH-2_EN, . . . CAL_CH-n_EN in order to provide the output of the counter 186 to a corresponding register 188_1 to 188_{—}n. The comparator 182, the level detect and control circuit 184, and the counter 186 may be commonly employed by one, some, or all of the strings 201_1, 201_2, . . . , 201_{—}n.

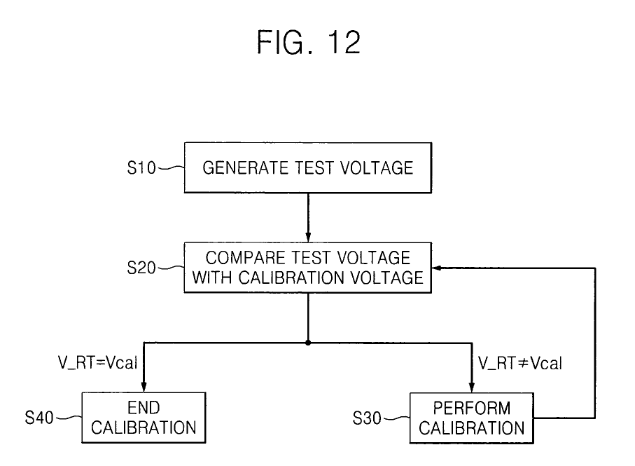

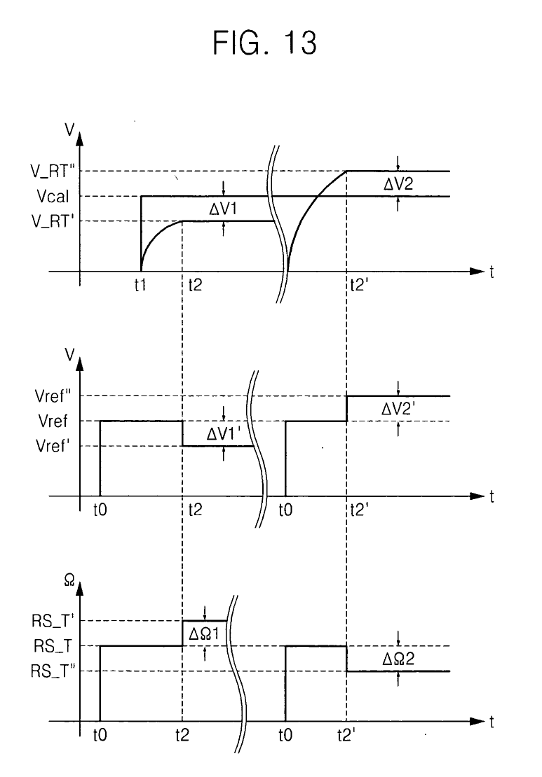

FIG. 12 illustrates a flowchart of the current calibrating operations of the driving IC 100 illustrated in FIG. 1. FIG. 13 illustrates waveforms according to the flowchart illustrated in FIG. 12. Although the current calibration performed by the driving IC 100 illustrated in FIG. 1 is described through the flowchart illustrated in FIG. 12 for clarity of the description, this flowchart may also be applied to the current calibration performed by any of the driving ICs 100a to 100d discussed above. Referring to FIGS. 1 and 12, when the driving IC 100 operates in a current calibration mode, the test current generator 151 of the current calibration circuit 150 may output the test current “It” and the second resistor 153 may output the test voltage V_RT according to the test current “It” in operation S10.

The test voltage V_RT is input to the calibrator 155 and the calibrator 155 may compare the test voltage V_RT with the calibration voltage Vcal in operation S20. When the test voltage V_RT is determined to be the same as the calibration voltage Vcal, for example, within an error tolerance, as a result of the comparison, the current calibration circuit 150 determines that no error has occurred in the resistance value of the second resistor 153 and ends the current calibration in operation S40.

When the current calibration is finished by the current calibration circuit 150, then no error has occurred in the first resistor 115 either. Accordingly, the driving IC 100 can maintain the load current IR flowing in the load 200 constant using the control voltage VG output as a result of comparing the reference voltage Vref which has not been calibrated with the load voltage V_RS output from the first resistor 115.

Meanwhile, when the test voltage V_RT is determined to be different from the calibration voltage Vcal, for example, beyond an error tolerance, as the result of the comparison by the calibrator 155, the calibrator 155 outputs the first current calibration control signal CNT1 or the second current calibration control signal CNT2 according to the comparison result to perform current calibration in operation S30. The first current calibration control signal CNT1 output from the calibrator 155 may be provided to the first resistor 115 (or the switch controller 160 in FIG. 2) to control the resistance value of the first resistor 115. The second current calibration control signal CNT2 output from the calibrator 155 may be provided to the reference voltage setup circuit 130 to control the magnitude of the reference voltage Vref.

For instance, when the calibrator 155 output the first current calibration control signal CNT1 or the second current calibration control signal CNT2, it may mean that an error has occurred in the resistance value of the second resistor 153. Accordingly, the calibrator 155 may output the first current calibration control signal CNT1 to compensate for an error in the resistance value of the first resistor 115, which occurs in the same amount as the error in the resistance value of the second resistor 153, or may output the second current calibration control signal CNT2 to calibrate the reference voltage Vref so that the error in the resistance value of the first resistor 115 can be compensated for.

The calibrator 155 may output only one control signal among the first and second current calibration control signals CNT1 and CNT2. In other words, the calibrator 155 may output either the first current calibration control signal CNT1 or the second current calibration control signal CNT2 to perform current calibration. After the current calibration is performed by the calibrator 155 in operation S30, the driving IC 100 may compare the test voltage V_RT with the calibration voltage Vcal again in operation S20.

Referring to FIGS. 1, 12, and 13, the reference voltage Vref may be output from the reference voltage setup circuit 130 at a time t0 on a time axis “t”. Also, a resistance value RS of the first resistor 115 may be measured at the time t0. At a time t1 on the time axis “t”, the driving IC 100 may operate in the current calibration mode and the calibration voltage Vcal may be input to the calibrator 155. Subsequently, the second resistor 153 may output a test voltage, e.g., a first test voltage V_RT′, to the calibrator 155 based on the test current “It” output from the test current generator 151 and the calibrator 155 may compare the first test voltage V_RT′ with the calibration voltage Vcal at a time t2.

When it is determined by the calibrator 155 that the first test voltage V_RT′ is less than the calibration voltage Vcal by a first voltage difference ΔV1 as the comparison result, the calibrator 155 may output the first current calibration control signal CNT1 or the second current calibration control signal CNT2 according to the comparison result. The first current calibration control signal CNT1 may control a resistance value RS_T′ of the first resistor 115 at the time t2. In detail, the first current calibration control signal CNT1 may control the resistance value RS_T′ of the first resistor 115 at the time t2 to be greater than the resistance value RS_T of the first resistor 115 measured at the time t0 by a first resistance difference ΔΩ1. The second current calibration control signal CNT2 may control the magnitude of a reference voltage Vref′ at the time t2. In detail, the second current calibration control signal CNT2 may control the reference voltage Vref′ at the time t2 to be less than the reference voltage Vref output at the time t0 by a first voltage difference ΔV1′. Accordingly, the load current control unit 110 can maintain the load current IR flowing in the load 200 constant due to the first resistor 115 whose resistance value has been controlled or the reference voltage Vref′ whose magnitude has been controlled, since the time t2 on the time axis “t”.

Alternatively, the reference voltage Vref may be output from the reference voltage setup circuit 130 at the time t0 on the time axis “t”. Also, the resistance value RS_T of the first resistor 115 may be measured at the time t0. At the time t1 on the time axis “t”, the driving IC 100 may operate in the current calibration mode and the calibration voltage Vcal may be input to the calibrator 155.

Subsequently, the second resistor 153 may output a test voltage, e.g., a second test voltage V_RT″, to the calibrator 155 based on the test current “It” output from the test current generator 151 and the calibrator 155 may compare the second test voltage V_RT″ with the calibration voltage Vcal at a time t2′. When it is determined by the calibrator 155 that the second test voltage V_RT″ is greater than the calibration voltage Vcal by a second voltage difference ΔV2 as the comparison result, the calibrator 155 may output the first current calibration control signal CNT1 or the second current calibration control signal CNT2 according to the comparison result.

The first current calibration control signal CNT1 may control a resistance value RS_T″ of the first resistor 115 at the time t2′. In detail, the first current calibration control signal CNT1 may control the resistance value RS_T″ of the first resistor 115 at the time t2′ to be less than the resistance value RS_T of the first resistor 115 measured at the time t0 by a second resistance difference ΔΩ2. The second current calibration control signal CNT2 may control the magnitude of a reference voltage Vref″ at the time t2′. In detail, the second current calibration control signal CNT2 may control the reference voltage Vref″ at the time t2′ to be greater than the reference voltage Vref output at the time t0 by a second voltage difference ΔV2′. Accordingly, the load current control unit 110 can maintain the load current IR flowing in the load 200 constant due to the first resistor 115 whose resistance value has been controlled or the reference voltage Vref″ whose magnitude has been controlled, since the time t2′ on the time axis “t”.

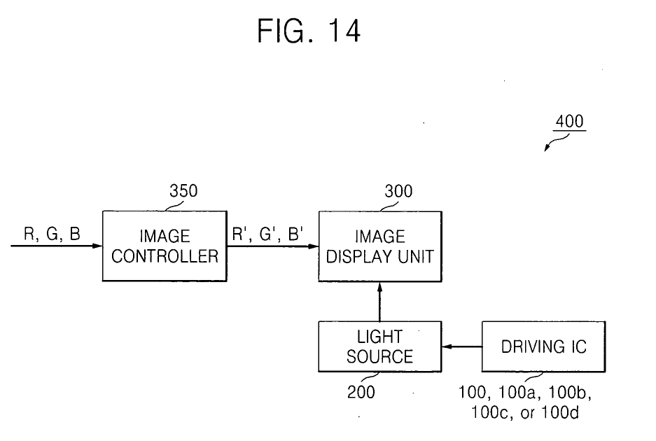

FIG. 14 illustrates a schematic block diagram of an image display device 400 including any of the driving ICs 100 to 100d discussed above. The image display device 400 may be a liquid crystal display (LCD) or an organic light emitting diode (OLED) display, but the present invention is not restricted thereto. Referring to FIG. 14, the image display device 400 may include an image display unit 300, an image controller 350, the light source 200, and the driving IC 100 to 100d′.

The light source 200 may include a plurality of the light sources, e.g., LEDs, LD1 through LDn, i.e., the load 200 illustrated above. The driving IC 100 to 100d has been described with reference to FIGS. 1 through 13. Thus, detailed description thereof will be omitted.

The image display unit 300 may display image signals R′, G′, and B′ provided from the image controller 350. The image controller 350 may process externally provided picture signals R, G, and B to be displayed by the image display unit 300, and may generate and output the image signals R′, G′, and B′ to the image display unit 300.

The light source 200 may provide light to the image display unit 300. The light source 200 may use a lamp or an LED. In the current embodiments of the present invention, it is assumed that the light source 200 uses a plurality of LEDs. The driving IC 100 to 100d may control a load current flowing in the LEDs to be constant.

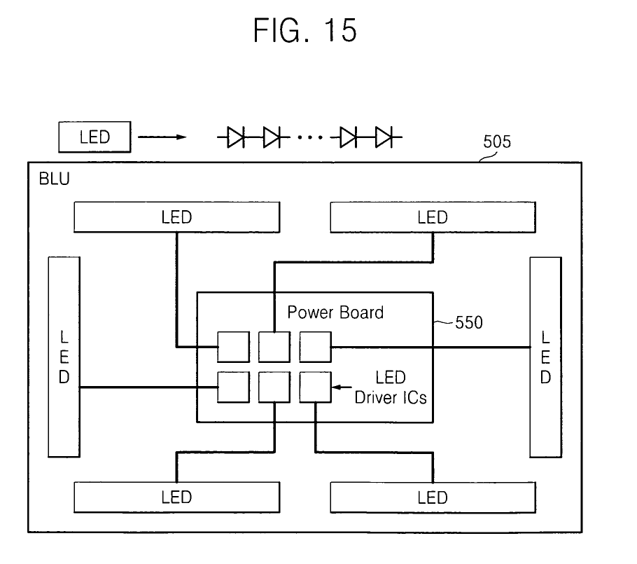

FIG. 15 illustrates a block diagram of a backlight unit (BLU) 505 for use with an exemplary edge type display 500 employing one or more features described herein, e.g., the driving IC 100 to 100d. Referring to FIG. 15, the BLU 505 may include a circuit board 550, a plurality of driving ICs, and a plurality of light sources, e.g., LEDs. The driving ICs may controllably drive respective ones of the plurality of light sources. The light sources may each include a single light source or a string of light sources. In some embodiments, each of the driving ICs may each correspond, e.g., to the driving ICs 100 to 100d, respectively. Accordingly, further description thereof will be omitted. Further, referring to FIG. 15, e.g., in edge type BLU TVs, the light sources may be arranged along one or more edges of the BLU 505. Although not shown, the edge type display may further include, e.g., an LCD display panel for which the BLU 505 may provide a uniform source of light. Edge type displays may be advantageous over direct type displays discussed below, e.g., may be relatively thinner displays.

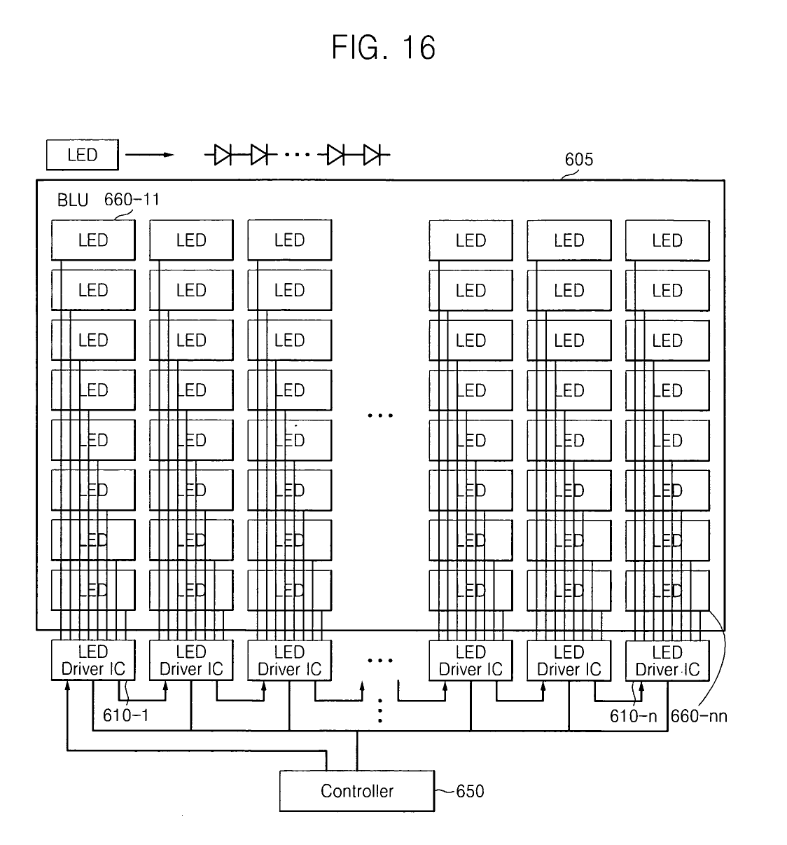

FIG. 16 illustrates a block diagram of an exemplary BLU 605 for use with a direct type display employing one or more features described herein, e.g., the driving ICs 100 to 100d. Referring to FIG. 16, the BLU 605 may include a plurality of driving ICs 610-1˜610-n and a controller 650. In some embodiments, the controller 650 may include, e.g., the reference voltage setup circuit 170 and/or be adapted to perform calibration of the reference voltage based on a respective voltage sensed by the driving ICs 610_1 to 610_{—}n. The BLU 605 may include a plurality of lights sources 660_11 to 660_{—}nn, e.g., LEDs, which may be arranged, e.g., in a matrix. In such embodiments, the driving ICs may controllably drive respective ones of the plurality of light sources arranged in a same column. The light sources may each include a plurality of light sources, but, in some embodiments may, be a single light source 601a. In some embodiments, each of the driving ICs may correspond, e.g., to any of the driving ICs 100 to 100d described above, etc. Accordingly, further description thereof will be omitted. Further, referring to FIG. 16, e.g., in direct type displays, the light sources may be arranged, e.g., in a matrix pattern. Although not shown, the direct type display may further include, e.g., an LCD display panel for which the BLU 605 may provide a uniform source of light.

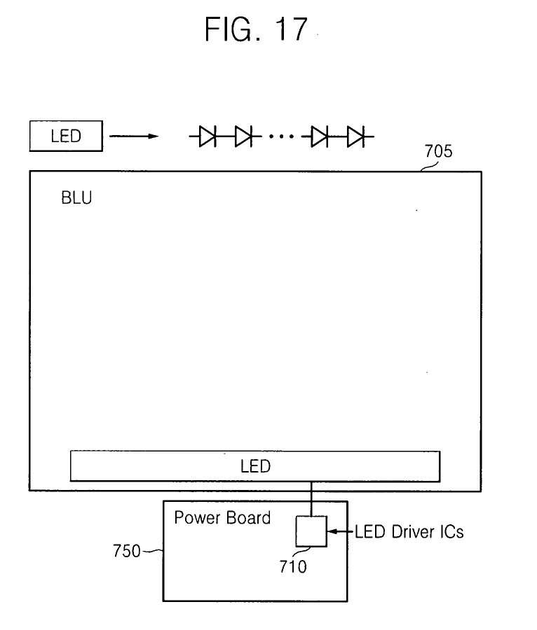

FIG. 17 illustrates a block diagram of an exemplary BLU 705 for use with a mobile device employing one or more features described herein, e.g., the driving ICS 100 to 100d. More particularly, e.g., the mobile device may be a mobile phone, a personal digital assistant (PDA), a smart phone, a portable multimedia player (PMP), an information technology (IT) device, e.g., projector, etc.

Referring to FIG. 17, the BLU 705 may include a light source, e.g., an LED, and a circuit board 750 including a driving IC 710. The driving IC 710 may controllably drive the light source. The light source may include a single light source or a string of light sources. In some embodiments, a plurality of light sources may be employed. In some embodiments, the light source driving IC may correspond, e.g., to the driving ICs 100 to 100d, respectively, described above. Accordingly, further description thereof will be omitted.

According to embodiments, a driving IC and an image display device including the same perform current calibration using an indirect resistance sensing method to maintain a load current flowing in a load constant, thereby increasing the accuracy of the current calibration and decreasing power consumption during the current calibration.

According to other embodiments, a driving IC and an image display device including the same perform current calibration using a direct resistance sensing method to generate a reference voltage to maintain a load current flowing in a load constant, thereby increasing the accuracy of the current calibration and decreasing power consumption during the current calibration.

While the present invention has been particularly shown and described with reference to exemplary embodiments thereof, it will be understood by those of ordinary skill in the art that various changes in forms and details may be made therein without departing from the spirit and scope of the present invention as defined by the following claims.

What is claimed is:

1. A driving integrated circuit (IC), comprising:
a reference voltage setup circuit configured to output a reference voltage based on a test voltage; and
a load current control unit configured to compare a load voltage output from a load resistor with the reference voltage in response to a load current flowing in a load and maintain the load current constant based on a result of the comparison.

2. The driving IC as claimed in claim 1, further comprising a test resistor configured to output the test voltage in response to a test current.

3. The driving IC as claimed in claim 2, wherein the load resistor includes at least two unit resistors connected in parallel and the test resistor includes at least two unit resistors connected in series.

4. The driving IC of claim 2, wherein a resistance value of the test resistor is an N multiple of a resistance value of the load resistor where N is a natural number.

5. The driving IC as claimed in claim 2, wherein the test resistor is part of the load current control unit.

6. The driving IC as claimed in claim 2, wherein the load and test resistors are adjacent to one another on a semiconductor substrate.

7. The driving IC as claimed in claim 1, wherein the reference voltage setup circuit includes a calibration circuit configured to compare the test voltage with a calibration voltage and output at least one control signal according to a result of the comparison to control the load current control unit to maintain the load current constant.

8. The driving IC as claimed in claim 7, wherein the at least one control signal comprises:
a first current calibration control signal output to the load resistor to control a resistance value of the load resistor; and
a second current calibration control signal output to the reference voltage generator to control a magnitude of the reference voltage, wherein
the calibration circuit outputs one of the first and second current calibration control signals.

9. The driving IC as claimed in claim 7, further comprising:
a switch controller configured to output a plurality of switching signals based on the at least one current calibration control signal; and
a switching unit including a plurality of switches respectively connected with the first unit resistors, the switching unit configured to perform switching operation in response to the switching signals to control the resistance value of the load resistor.

10. The driving IC as claimed in claim 7, wherein the test voltage is an actual value output from a test resistor in response to a test current and the calibration voltage is a theoretical value calculated from the test current and a resistance value of the test resistor.

11. The driving IC as claimed in claim 1, wherein the load current control unit comprises:
a comparator configured to compare the load voltage with the reference voltage and output the comparison result; and
a controller connected with the load and configured to maintain a magnitude of the load current constant according to the comparison result output from the comparator.

12. The driving IC as claimed in claim 1, wherein the load comprises a plurality of light emitting diodes (LEDs) and the driving IC is an LED driving IC.

13. The driving IC as claimed in claim 2, further comprising a test current source connected to the test resistor supplying the test current.

14. The driving IC as claimed in claim 13, wherein the test current source is turned off when calibration is complete.

15. The driving IC as claimed in claim 1, wherein the reference voltage setup circuit includes a calibration circuit configured to receive the test voltage.

16. The driving IC as claimed in claim 15, wherein the reference voltage setup circuit includes a reference voltage generation circuit configured to output the reference voltage.

17. The driving IC as claimed in claim 16, wherein the reference voltage generation circuit is configured to output variable voltages to the calibration circuit and the calibration circuit includes a comparator comparing the variable voltages to the test voltage.

18. The driving IC as claimed in claim 17, wherein the load current control unit includes a comparator configured to compare the load voltage with the reference voltage and output the comparison, the comparator in the load current control unit being a same type as the comparator in the calibration circuit.

19. An image display device, comprising:
an image display unit configured to display an image signal;
a light source configured to provide light to the image display unit; and
a driving integrated circuit (IC) configured to maintain a load current applied from the outside to the light source constant, the driving IC including:
a reference voltage setup circuit configured to output a reference voltage based on a test voltage, and
a load current control unit configured to compare a load voltage output from a load resistor with the reference voltage in response to a load current flowing in a load and maintain the load current constant based on a result of the comparison.

20. The image display device as claimed in claim 19, wherein the image display unit is a large panel display unit.

21. The image display device as claimed in claim 20, wherein the light source includes a plurality of light sources arranged in a periphery of the large panel display unit.

22. The image display device as claimed in claim 20, wherein the light source includes a plurality of light sources arranged in a matrix adjacent the large panel display unit.

23. The image display device as claimed in claim 19, wherein the image display unit is a portable display unit.

24. The image display device as claimed in claim 23, wherein the light source includes a plurality of light sources arranged in a periphery of the portable display unit.

25. The image display device as claimed in claim 23, wherein the light source includes a plurality of light sources arranged in a matrix adjacent the portable display unit.

26. A back light unit for an image display device, comprising:
a light source configured to provide light to the image display device; and
a driving integrated circuit (IC) configured to maintain a load current applied from an outside to the light source constant, the driving IC including:
a reference voltage setup circuit configured to output a reference voltage based on a test voltage, and
a load current control unit configured to compare a load voltage output from a load resistor with the reference voltage in response to a load current flowing in a load and maintain the load current constant based on a result of the comparison.

27. The back light unit of claim 26, wherein the light source includes a plurality of light emitting diode (LED) sources arranged in a periphery of the back light unit.

28. The back light unit of claim 26, wherein the light source includes a plurality of light emitting diode (LED) sources arranged in a matrix.

29. The back light unit of claim 26, wherein the light source includes a light emitting diode (LED) source for a mobile device.

30. A multi-channel driving system, comprising:
a plurality of driving integrated circuits (ICs);
a reference voltage setup circuit adapted to supply respective reference voltages to each of the plurality of driving ICs, the reference voltage generation circuit including a reference voltage source adapted to supply source reference voltages based on test voltages; and
a calibration circuit configured to receive a sensed voltage from each of the driving ICs and to generate a respective reference voltages in accordance with each of the sensed voltages and a respectively selected one of the source reference voltages.

31. The multi-channel driving system as claimed in claim 30, wherein at least one of the reference voltage source and the calibration circuit are common to the plurality of driving ICs.

32. A method of driving a light source, comprising:
calibrating a reference voltage in accordance with a test voltage;
supplying the reference voltage to a current driver when calibrating is complete; and
driving the light source with the current driver.

33. The method as claimed in claim 32, further comprising, when calibrating is complete, stopping calibrating.

34. The method as claimed in claim 32, further comprising generating the test voltage using a test resistor, adjacent a resistor in the current driver, connected to a test current source.

35. The method as claimed in claim 34, further comprising turning off the test current source when calibrating is complete.
